(19) United States
(12) Patent Application Publication
(10) Pub. No.: US 2013/0032207 A1
(43) Pub. Date: Feb. 7, 2013

(54) METHOD FOR CONTACT-CONNECTING A PHOTOVOLTAIC MODULE TO A CONNECTION HOUSING AND SYSTEM CONSISTING OF A PHOTOVOLTAIC MODULE AND A CONNECTION HOUSING

(71) Applicants: Patrick Oberrisser, Judenburg (AT); Gernot Gmundner, Kraubath (AT)

(72) Inventors: Patrick Oberrisser, Judenburg (AT); Gernot Gmundner, Kraubath (AT)

(21) Appl. No.: 13/641,928

(22) PCT Filed: Apr. 20, 2011
(86) PCT No.: PCT/AT2011/000192

§ 371 Date: Oct. 18, 2012

(30) Foreign Application Priority Data
Apr. 27, 2010 (AT) GM 270/2010

(51) Int. Cl. H01L 31/0224; H01L 31/18

(52) U.S. Cl. 136/256; 438/64; 257/E31.124

(57) ABSTRACT

In a method and system consisting of a photovoltaic module and a connection housing or a junction box, wherein the photovoltaic module comprises at least one solar cell which is coupled at a rear side to an electrically conductive and structured layer for conducting away the electrical energy generated in a solar cell, and, furthermore, at least one transparent carrier layer and a covering layer are provided, wherein the electrically conducting layer can be contact-connected to connections of the connection housing, it is proposed that connections or connection elements of the connection housing can be coupled directly to partial regions having different polarities of the conducting layer via at least one through-opening in the covering layer, as a result of which contact-connection of a photovoltaic module to connection elements of a connection housing can be obtained in a simple and reliable manner.

This is national stage of PCT/AT2011/000192, filed Apr. 20, 2011 and published in German, which has a priority of Austria no. GM 270/2010, filed Apr. 27, 2010, hereby incorporated by reference.

### FIELD OF THE INVENTION

The present invention relates to a method for contact-connecting a photovoltaic module to a connection housing or junction box, wherein, for producing the photovoltaic module, at least one solar cell is coupled on a rear side to an electrically conducting or conductive and structured layer for conducting away the electrical energy generated in the solar cell, and at least one transparent carrier layer is provided on the surface of the solar cell facing away from the electrically conducting layer and a covering layer is provided on the electrically conducting layer, wherein the electrically conducting and structured layer is subsequently contact-connected to connections of the connection housing. The present invention, moreover, relates to a system consisting of a photovoltaic module and a connection housing or junction box, wherein the photovoltaic module comprises at least one solar cell which is coupled on a rear side to an electrically conducting or conductive and structured layer for conducting away the electrical energy generated in a solar cell and, furthermore, at least one transparent carrier layer is provided on the surface of the solar cell facing away from the electrically conducting layer, and a covering layer is provided on the electrically conducting layer, wherein the electrically conducting and structured layer can be contact-connected to connections of the connection housing.

### PRIOR ART

Such a so-called rear-side-contact-connected photovoltaic module consists of at least one solar cell, which solar cell is coupled or coupleable on a rear side to an electrically conducting or conductive and structured layer for conducting away the electrical energy generated in the solar cell. In addition, at least one transparent carrier layer is provided on the solar cell surface facing away from the electrically conducting layer, and hence directed to the radiation source, and a cover layer is provided on the electrically conducting layer.

To carry away the electrical energy generated in the solar cell, wherein usually a plurality of solar cells are mutually coupled in a common carrier element via the electrically conducting or conductive and structured layer, a contact-connection to connections of the connection housing is subsequently established. According to known embodiments, slots are made in the cover layer for passing through contact or solder strips, which are connected to partial regions of the electrically conducting and structured layer in expensive or laborious method steps. After the arrangement of the connection housing or junction box, a contact-connection or wiring is formed between the contact or solder strips passed through the slot in the cover layer of the photovoltaic module and the respective contacts of the connection housing, which again involves expenditures. Such a method and system can, for instance, be taken from U.S. Pat. No. 6,469,242, from which it is, in particular, apparent that the formation of slots and suitable passages for passing through the solder strips not only involves extremely high operating expenditures for the contact-connection to be made, but also does not reliably ensure the tightness of the photovoltaic module required for proper functioning.

### SUMMARY OF THE INVENTION

The present invention aims to avoid the problems of the above-cited prior art and hence provide a method for contact-connecting a photovoltaic module to a connection housing or junction box, as well as a system comprised of a photovoltaic module and a connection housing, in which a reliable and simple contact-connection can be established, in particular by simplified method steps, between the electrically conducting and structured layer of the photo-voltaic module and respective contacts or connections or connection elements of the connection housing or junction box.

To solve these objects, a method of the initially-defined kind is substantially characterized in that, after the completion of the photovoltaic module for instance by compression and/or heat exposure of the layers or elements forming the photovoltaic module, at least one through-opening for exposing partial regions having different polarities of the structured conducting layer is formed in the covering layer, and connections or connection elements of the connection housing are directly coupled to said partial regions having different polarities of the structured conducting layer. In that it is proposed according to the invention that, after the completion of the photo-voltaic module, at least one through-opening for exposing partial regions having different polarities of the structured conducting layer of the photovoltaic module is formed in the covering layer of the same, and connections or connection elements of the connection housing are directly coupled to said partial regions having different polarities, a strongly simplified and more reliable contact-connection will be provided compared to the known methods and systems, according to which a contact-connection has been made via solder strips to be contact-connected several times and to be conducted through appropriate slots in the photovoltaic module. By renouncing the formation of slots at least in the cover layer, and usually further layers, of the photovoltaic module, it will, moreover, also be ensured that the tightness of the photovoltaic module, particularly in the region of the contact-connection to connections of the connection housing, will not be affected. In accordance with the invention, at least one through-opening for exposing partial regions having different polarities of the structured conducting layer is only provided in the covering layer, wherein the necessary tightness of the whole photovoltaic module, in particular against the penetration of, for instance, moisture, can be reliably maintained by the aid of the layer of conducting or conductive material, which is connected to further layers or plies of the photovoltaic module, for instance by compression and/or heat exposure. By the method according to the invention, it is thus not only feasible to realize, in a simplified and rapid manner, the contact-connection between the electrically conducting or conductive and structured layer of the photovoltaic module and connections or contacts or connection elements of the connection housing, but the tightness required for the proper functioning of the photo-voltaic module will, in particular, also be reliably maintained without taking any additional measures or precautions.

For a particularly simple configuration of the at least one through-opening in the covering layer of the photovoltaic module, it is proposed according to a preferred embodiment that the at least one through-opening is exposed by mechanically removing a partial region of the covering layer, by milling, etching, or the like. Such methods for forming through-openings in a layer or ply optionally having a slight thickness can be performed in an accordingly reliable and precise and gentle manner so as to avoid impairment of, in particular, the tightness of the photovoltaic module in regions surrounding the through-opening as against known embodiments, in which slot-shaped passages are usually formed through a plurality of layers or plies.

According to a particularly preferred embodiment, it is proposed in this respect that etching is performed by using a laser, wherein a UV laser or a CO₂ laser can, for instance, be employed, particularly as a function of the material of the covering layer of the photovoltaic module.

To subsequently enable simple and reliable contact-connecting or coupling between the partial regions having different polarities of the electrically conducting and structured layer of the photovoltaic module and respective contacts or connections of the connection housing, it is, moreover, proposed that direct contact-connecting to connections or connection elements of the connection housing is effected by solder bonding, adhesive bonding, or the like, as in correspondence with a further preferred embodiment of the method according to the invention.

In order to provide a tight closure of the photovoltaic module, and for the simple performance of, in particular, method steps applied in the manufacture of the photovoltaic module, it is proposed according to a further preferred embodiment that the covering layer is comprised of at least one synthetic layer, e.g. a polyvinylfluoride film.

In order to further improve the, in particular tight, construction of the photovoltaic module, and to simplify the contact-connection to connections or connection elements of the connection housing, it is, moreover, proposed that the electrically conducting and structured layer and the covering layer are formed by a compound film which is connected or coupled to the solar cell, as in correspondence with a further preferred embodiment of the method according to the invention.

While known embodiments for contact-connecting to contacts of the connection housing the contact or solder strips that are cumbersome to insert have involved extremely high expenditures in terms of manufacturing engineering, it is proposed according to a further preferred embodiment that the positioning of the connection housing on the covering layer is effected automatically after the formation of the at least one through-opening. The expenditures involved in contact-connecting the connection housing are thus accordingly strongly reduced over known methods.

To solve the initially mentioned objects, a system consisting of a photovoltaic module and a connection housing or a junction box of the initially-defined kind is, moreover, essentially characterized in that connections or connection elements of the connection housing can be directly coupled to partial regions having different polarities of the structured conducting layer via at least one through-opening in the covering layer. By providing the at least one through-opening while exposing partial regions having different polarities of the structured conducting layer, it has become possible to provide a particularly simple and reliable contact-connection to contacts or connections or connection elements of the connection housing, as already pointed out above. In addition, the tightness of the multilayer or multi-ply assembly required for the proper functioning of the photovoltaic module will likewise be ensured or reliably maintained.

For a particularly reliable and simple manufacture of the photovoltaic module while, at the same time, enabling a reliable contact-connection to connections or connection elements of the connection housing, it is, moreover, preferably proposed that the electrically conducting layer and the covering layer are formed by a compound film.

For a particularly simple and reliable contact-connection or coupling between connections or contacts or connection elements of the connection housing and the partial regions of the structured conducting layer, it is, moreover, proposed that the connections of the connection housing are each coupleable to a conducting element, which is each contact-connectable, and hence coupleable, to a partial region of different polarity of the structured conducting layer via the through-opening, particularly by an adhesive or solder bond, as in correspondence with a further preferred embodiment of the system according to the invention. In this manner, the connecting operation between the photo-voltaic module and contacts or connections or connection elements of the connection housing can be simplified and advantageously largely automated, as already indicated above.

For a particularly reliable contact-connection while, in particular, avoiding the use of accordingly expensive additional elements, it is proposed according to a further preferred embodiment that the conducting element is comprised of an element made of a conducting material, in particular a solder strip, or the like.

In order to further reduce the components or individual elements of, in particular, the connection housing, and to avoid losses during the energy transmission over a large number of junctions, it is proposed according to a further preferred embodiment that the connections of the connection housing are each directly contact-connectable, and hence coupleable, to a partial region of different polarity of the structured conducting layer via the through-opening.

In order to ensure a reliable fixation of the connection housing to the photovoltaic module and additionally provide appropriate sealing in the region of the connection housing, it is proposed according to a further preferred embodiment that the connection housing is sealingly fixable to the photovoltaic module, particularly by an adhesive bond.

### SHORT DESCRIPTION OF THE DRAWINGS

In the following, the invention will be explained in more detail by way of exemplary embodiments schematically illustrated in the accompanying drawing. Therein:

FIG. 1 depicts a schematic section through a system comprising a photovoltaic module and a connection housing according to the known prior art;

FIG. 2, in an illustration similar to that of FIG. 1, depicts a section through a system according to the invention, comprising a photovoltaic module and a connection housing produced by the method according to the invention;

FIG. 3 is a schematic top view of the system illustrated in FIG. 2, along arrow III of FIG. 2;

FIG. 4, again in an illustration similar to that of FIG. 2, shows a further modified embodiment of a system according to the invention;

FIG. 5, in an illustration similar to that of FIG. 4, again shows a modified embodiment of a system according to the invention with connections of a connection housing being directly coupled to the conducting, structured layer; and

FIG. 6 is a schematic flow diagram of the method according to the invention for contact-connecting a photovoltaic module to a connection housing.

### DETAILED DESCRIPTION OF PREFERRED EMBODIMENTS

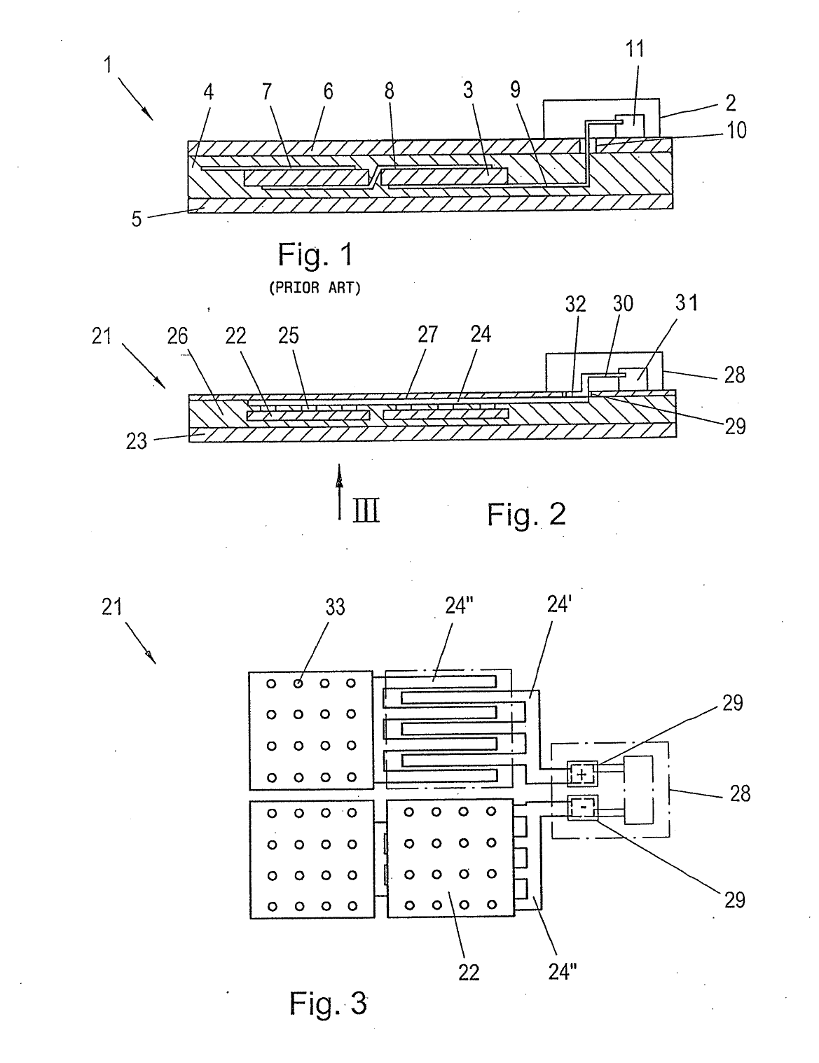

FIG. 1 depicts a schematic section through a known photo-voltaic module 1 and a connection housing or junction box 2 fixed thereto, from which it is apparent that a plurality of cells or solar cells 3 are each embedded in at least one synthetic layer made, for instance, of ethylene vinyl acetate. Additionally provided are a transparent carrier layer 5 which is, for instance, made of glass and directed to a radiation source not illustrated in detail, and a cover layer 6.

The adjacent cells 3 are connected in series and interconnected by contact paths 7 and 8. For coupling to a connection housing 2 to be subsequently fixed to the cover layer 6, additional contact or solder strips 9 are provided, which pass through a slot-shaped opening or cut 10 provided in the cover layer 6 and are each contact-connected to a schematically indicated connection or contact 11 in the connection housing 2. Due to the formation of the slot or cut 10, which at least partially penetrates not only the cover layer 6 but also the synthetic layer 4 provided for embedding, such known embodiments according to the prior art not only involve a problem in respect to the required tightness of the photovoltaic module 1, but also call for increased expenditures for establishing the contact-connection to the contacts 11 of the connection housing 2.

Also for solar cells only contact-connected on their rear sides, the prior art contemplates conducting solder strips through cuts or slots 10 penetrating the cover layer 6, and at least partially also the layer 4, to carry away the generated energy, including the above-mentioned drawbacks.

FIGS. 2 and 3 depict a sectional view similar to the illustration according to FIG. 1 and a top view, respectively, of a system according to the invention, wherein it is apparent, in particular from the illustration according to FIG. 3, that the photovoltaic module 21 comprises a plurality of cells or solar cells 22. The solar cells 22, on their surfaces facing away from a transparent layer 23 optionally made of glass, or rear sides, are each contact-connected to a structured, electrically conducting or conductive layer 24 via schematically indicated contacts 25. In addition, contacts or junctions enabling a contact-connection through the solar cells 22 to the conducting and structured layer 24 disposed on the rear side thereof are schematically indicated by 33 in FIG. 3.

The pattern of the conducting or conductive layer 24 is, in particular, apparent from the right-hand upper partial area of the illustration according to FIG. 3, wherein it is shown that mutually engaging, substantially prong-shaped or fork-shaped elements of the structured or patterned layer each have different polarities as indicated by + and − connections. The partial regions having different polarities are schematically indicated by 24′ and 24″ in FIG. 3.

As in the embodiment according to the prior art, the solar cells 22 according to FIG. 1 are embedded in a synthetic material or synthetic layer 26 made, for instance, of ethylenevinylacetate.

On the side facing away from the transparent base layer 23, which is again directed to a radiation source not illustrated, a cover layer 27 comprised, for instance, of a polyvinylfluoride film is, moreover, provided.

For the simple provision of the electrically conducting or conductive layer 24, it may, moreover, be provided that a compound film comprised of the cover layer 27 and the patterned, electrically conducting layer 24 is provided, wherein either the compound film is formed directly with the patterned, electrically conducting or conductive layer corresponding to paths 24′ and 24″, or such a pattern is produced on the substantially full area-conducting or—conductive layer after the provision of the compound film, for instance by known etching processes.

For the contact-connection of a connection housing 28 to the different polarity partial regions + and −, respectively, through-openings 29 are formed in the cover layer 27, which open directly at the different polarity partial regions + and −, respectively, of the structured conducting layers 24′ and 24″.

In the region of the through-opening 29, the immediate or direct contact-connection to connection elements 30 of the connection housing 28 including connections or contacts 31 is effected.

The connection housing 28 can thus be immediately provided with the connection elements 30 additionally to the contacts 31, with free ends 32 of the connection elements 30 directly entering the through-openings 29 and being contact-connected to the regions having different polarities + and −, respectively, of the structured conducting layer 24′, 24″.

Such a contact-connection can, for instance, be accomplished by a solder joint, as will be discussed in more detail, in particular, with reference to FIG. 5.

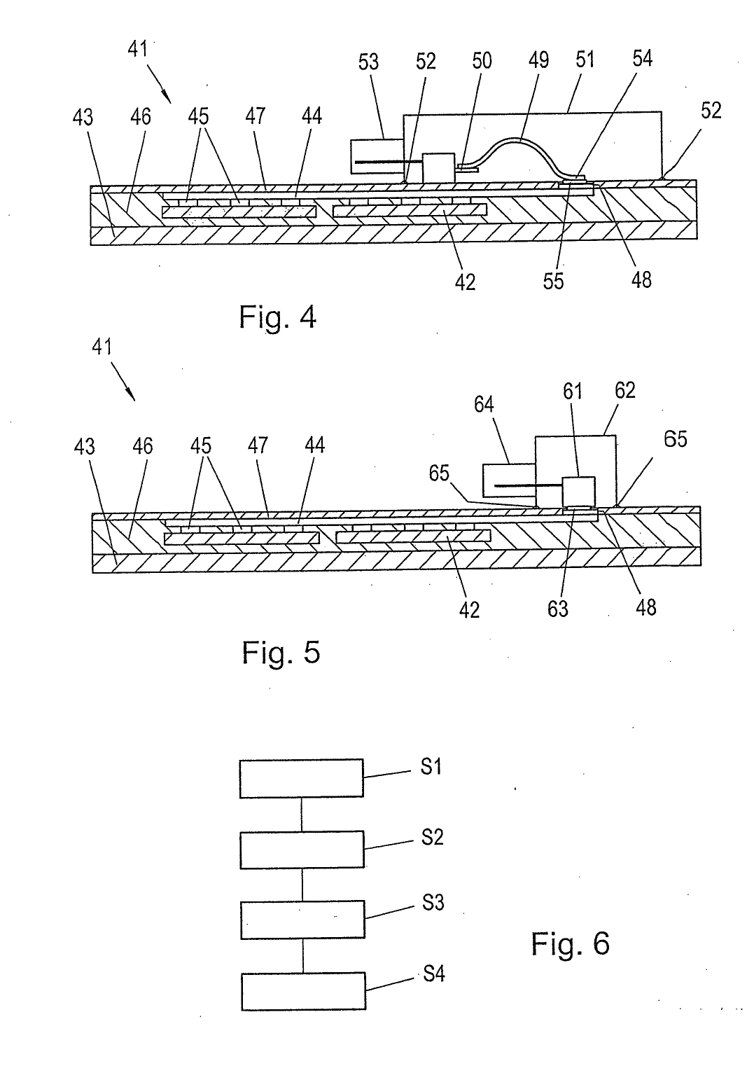

In the modified embodiment according to FIG. 4, a photovoltaic module 41 again comprises a plurality of cells 42, a transparent base or carrier layer being denoted by 43. The cells 42, via schematically indicated contacts 45, are connected to a structured conducting layer 44 disposed on the rear side and, hence, on the side facing away from the transparent layer 43, wherein the solar cells 42 are again embedded in a synthetic layer 46. The contacts passing through the cells 42 are not shown as in the illustration according to FIG. 2. A cover layer 47 is again provided on the side facing away from the carrier layer 43.

For contact-connecting, at least one through-opening 49 is again formed in the cover layer 47 in the embodiment depicted in FIG. 4 in order to expose partial regions having different polarities, of the structured conducting or conductive layer 44. In the embodiment according to FIG. 4, the connection element is again formed by a solder strip 49 integrated in the connection housing 51 and again connected to a schematically indicated contact 50, similarly as in the preceding embodiment. The connection housing 51 is fixed to the cover layer 47 by schematically indicated adhesive bonds 52, wherein a connector of the connection housing 51 is, for instance, additionally schematically indicated by 53.

In the region of the at least one through-opening 48, an adhesive material or solder material 55 is additionally indicated for the contact-connection between the free end 54 and a respective partial region of different polarity of the structured layer 44.

In the illustration according to FIG. 5, the reference numerals of FIG. 4 have been retained for identical elements or components. Thus, a photovoltaic module 41 comprises a plurality of solar cells 42, with a transparent base or carrier layer 43 being additionally provided.

Contact-connecting of the cells 42 is effected by means of a structured and conducting layer 44 via schematic contacts 45, wherein a synthetic layer 46 is provided for embedding the solar cells 42. A cover layer is again provided with at least one through-opening 48 for exposing partial regions having different polarities of the structured conducting layer 44.

Instead of using connection elements made of a conducting material as in the embodiments of FIGS. 2 and 4, the configuration according to FIG. 5 provides that connections or contacts 61 of a connection housing 62 are directly contact-connected or connected to the partial regions having different polarities of the layer 44 via an adhesive or solder bond 63. Similarly as in the embodiment according to FIG. 4, a connector 64 is also provided or indicated for the connection housing 62.

Schematically indicated adhesive bonds 65 are provided to fix the connection housing 62 to the cover layer 47.

Because of the direct contact-connection provided in the embodiment according to FIG. 5 between the exposed partial regions having different polarities via the through-openings 48 and the connections or contacts 61 of the connection housing 62, the expenditures required for the contact-connection or coupling of the photovoltaic module 41 to the connection housing 62 can thus be further reduced and simplified.

Due to the fact that in the embodiments according to FIGS. 2, 4 and 5 at least one through-opening 29 or 48, respectively, is only formed in the region of the connections having different polarities of the conducting and structured later 24 or 44, respectively, the integrity of the photovoltaic module 21 and 41, respectively, and, in particular, the tightness of the same in the region of connection and of the arrangement of the connection housing and 51 or 62, respectively, will be safeguarded and reliably maintained.

In the schematic flow diagram of FIG. 6, the construction known per se of a rear-side-contact-connected photovoltaic module is performed in step Si by coupling solar cells to the respectively patterned, conductive layer while embedding them into a synthetic material. In addition, the connection to the base or carrier material and the arrangement of the cover layer take place.

After having completed the photovoltaic module according to step S1, the formation of at least one through-opening in the cover layer to expose partial regions having different polarities of the conducting and patterned layer is performed in step S2.

The exposure of at least one through-opening in the cover layer can be accomplished by mechanically removing the respective partial region, by milling or by etching, in particular as a function of the material of the cover layer.

Particularly when using a compound film comprised of the cover layer and the conducting or conductive layer, the removal of a partial region of the cover layer by the aid of a laser is proposed to form the through-opening.

Such a step S2 of forming the through-opening using a laser can be performed by applying the following parameters:

Total capacity: 1.1 Watt
Point size: 5.65 μm
Capacity: about 48 mJ per shot

After having exposed the through-opening in this manner, polishing also by the aid of a UV laser is proposed to improve the contact-connection, wherein the following parameters are applied:

Total capacity: 0.8 Watt
Point size: 13.33 μm
Capacity: about 27 mJ per shot

Instead of using a UV laser, a CO₂ laser may, for instance, be employed, particularly as a function of the material of the cover layer, in particular in a multi-stage process.

Moreover, the combined use of a UV laser and a CO₂ laser can be envisaged for the production of the through-opening in the cover layer.

After having exposed the partial regions of different polarities while forming at least one through-opening in the cover layer according to step S2, a conductive adhesive or a solder paste is applied in step S3 to the exposed partial regions having different polarities of the structured and conductive layer of the photovoltaic module.

After this, by placing and fixing the connection housing according to step S4 using, for instance, an adhesive, a contact-connection is each immediately effected, either of free ends of the connection elements in the configuration according to FIG. 2 or 4, or of the connections of the connection housing according to FIG. 5, in the region of the at least one through-opening to the partial regions having different polarities of the structured and conducting layer.

The method described with reference to FIG. 6 can be performed in an accordingly automated manner such that, compared to the known prior art as discussed, for instance, with reference to FIG. 1, the contact-connection of a photovoltaic module to connection elements or connections of a connection housing can be performed at strongly reduced time and cost expenditures and, in particular, with increased precision. Moreover, the integrity or tightness of the photovoltaic module completed according to step S1 will remain unaffected, since the required sealing effect will even be maintained in the region of the through-opening in the cover layer by the layer of patterned conducting material arranged therebelow.

1. A method for contact-connecting a photovoltaic module to a connection housing or junction box, wherein, for producing the photovoltaic module, at least one solar cell is coupled on a rear side to an electrically conducting or conductive and structured layer for conducting away the electrical energy generated in the solar cell, and at least one transparent carrier layer is provided on the surface of the solar cell facing away from the electrically conducting layer and a covering layer is provided on the electrically conducting layer, wherein the electrically conducting and structured layer is subsequently contact-connected to connections of the connection housing, wherein, after the completion of the photovoltaic module for instance by compression and/or heat exposure of the layers or elements forming the photovoltaic module, at least one through-opening for exposing partial regions having different polarities of the structured conducting layer is formed in the covering layer, and connections or connection elements of the connection housing are directly coupled to said partial regions having different polarities of the structured conducting layer, wherein the electrically conducting and structured layer and the covering layer are formed by a compound film which is connected or coupled to the solar cell.

2. The method according to claim 1, wherein the at least one through-opening is exposed by mechanically removing a partial region of the covering layer, by milling, etching, or the like.

3. The method according to claim 2, wherein etching is performed by using a laser.

4. The method according to claim 1, wherein direct contact-connecting to connections or connection elements of the connection housing is effected by solder bonding, adhesive bonding, or the like.

5. The method according to claim 1, wherein the covering layer is comprised of at least one synthetic layer, e.g. a polyvinylfluoride film.

6. The method according to claim 1, wherein the positioning of the connection housing on the covering layer is effected automatically after the formation of the at least one through-opening.

7. A system consisting of a photovoltaic module and a connection housing or junction box, wherein the photovoltaic module comprises at least one solar cell which is coupled on a rear side to an electrically conducting or conductive and structured layer for conducting away the electrical energy generated in a solar cell and, furthermore, at least one transparent carrier layer is provided on the surface of the solar cell facing away from the electrically conducting layer, and a covering layer is provided on the electrically conducting layer, wherein the electrically conducting and structured layer can be contact-connected to connections of the connection housing, wherein connections or connection elements of the connection housing can be directly coupled to partial regions having different polarities of the structured conducting layer via at least one through-opening in the covering layer, wherein the electrically conducting layer and the covering layer are formed by a compound film.

8. The system according to claim 7, wherein the connections of the connection housing are each coupleable to a conducting element, which is each contact-connectable, and hence coupleable, to a partial region of different polarity of the structured conducting layer via the through-opening, particularly by an adhesive or solder bond.

9. The system according to claim 8, wherein the conducting element is comprised of an element made of a conducting material, in particular a solder strip, or the like.

10. The system according to claim 7, wherein the connections of the connection housing are each directly contact-connectable, and hence coupleable, to a partial region of different polarity of the structured conducting layer via the through-opening.

11. The system according to claim 7, wherein the connection housing is sealingly fixable to the photovoltaic module, particularly by an adhesive bond.

12. (canceled)

13. (canceled)
